(19) United States
(12) Patent Application Publication
(10) Pub. No.: US 2008/0244925 A1
(43) Pub. Date: Oct. 9, 2008

(54) AIR KNIFE AND SUBSTRATE DRYING APPARATUS HAVING THE SAME

(75) Inventor: Sang-Min SHIN, Cheonan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/098,091

(22) Filed: Apr. 4, 2008

(30) Foreign Application Priority Data
Apr. 4, 2007 (KR) 10-2007-0033089

(51) Int. Cl. F26B 9/00

(52) U.S. Cl. 34/611

(57) ABSTRACT

An air knife capable of preventing drying defects during substrate drying processes includes an inlet through which air is supplied from an outside of the air knife, a chamber which stores the air flowing through the inlet, and an outlet which is connected to the chamber and sprays the air stored in the chamber on a substrate, and a main body having a lower end portion extending from the outlet and past at least a portion of the chamber, wherein an angle between the lower end portion of the main body and a body reference line extended from the outlet is less than 40 degrees.

This application claims priority to Korean Patent Application No. 10-2007-0033089, filed on Apr. 4, 2007, and all the benefits accruing therefrom under 35 U.S.C. §119, the contents of which in its entirety are herein incorporated by reference.

### BACKGROUND OF THE INVENTION

1. Field of the Invention

The present invention relates to an air knife and a substrate drying apparatus having the same. More particularly, the present invention relates to an air knife capable of preventing drying errors during substrate drying processes, and a substrate drying apparatus having the same.

2. Description of the Related Art

Generally, semiconductor components and elements sensitively react to minute particles. The minute particles have influence on the characteristics of those components or elements, and even on a semiconductor device. For the above reason, semiconductor processes focus on minute particles control, and cleaning processes are repeatedly carried out according to semiconductor process conditions.

Recently, electronic display industries of semiconductor industries have developed, and large sized liquid crystal display (“LCD”) devices have emerged. Such LCD devices undergo many surface treatment processes, for example, thin film forming processes and the like. Cleaning and drying processes are essential in the surface treatment processes to manufacture the LCD devices. The drying processes are implemented by drying apparatuses. Most of the drying apparatuses have adopted an air spray method.

In more detail, the drying apparatuses remove cleaning agents or impurities remaining on surfaces of substrates and circuit elements by air pressure, after cleaning the minute particles or impurities attached to the surfaces of the substrates or circuit elements.

The drying apparatuses include an air knife for spraying air in the vicinity of the substrate.

### BRIEF SUMMARY OF THE INVENTION

It has been determined herein, according to the present invention, that during conventional air spraying processes, since vortex air currents are generated at a rear portion of the air current sprayed from a conventional air knife, the cleaning agents and the impurities flow into a dried area of a liquid crystal display (“LCD”) panel. As a result, the quality of the LCD is degraded due to the cleaning agents and the impurities during manufacturing processes of the LCD devices.

The present invention, however, provides an air knife capable of preventing any impurities from flowing into a dried area of a substrate during substrate drying processes, and a substrate drying apparatus having the same.

In exemplary embodiments of the present invention, an air knife includes an inlet through which air is supplied from an outside of the air knife, a chamber which stores the air flowing through the inlet, an outlet which is connected to the chamber and sprays the air stored in the chamber on a substrate, and a main body having a lower end portion extending from the outlet and past at least a portion of the chamber, wherein an angle between the lower end portion of the main body and a body reference line extended from the outlet is less than 40 degrees.

The air knife may further include a throat that connects the chamber to the outlet.

The air sprayed through the outlet may make a predetermined angle with respect to the surface of the substrate, at about 10° to about 50°, wherein the predetermined angle is greater than the angle between the lower end portion of the main body and a body reference line.

A distance between the lower end portion of the main body and the substrate increases as a distance increases from the outlet.

The body reference line may be a longitudinal axis passing longitudinally through the chamber and the throat, the chamber may have a larger cross-sectional area than the throat, and the distance between the lower end portion of the main body and the body reference line may gradually increase from the outlet to a first point of the chamber connected to the throat and from the first point of the chamber to a second point of the chamber closer to the inlet.

The angle is more preferably about 0° to about 30°.

A distance between the one side of the main body and the substrate increases as a distance increases from the outlet.

The air knife may further include a throat which connects the chamber to the outlet, and a cross-sectional area of a first part connecting the chamber and the throat gradually decreases toward the throat, and a cross-sectional area of a second part connecting the throat and the outlet gradually increases toward the outlet.

In still other exemplary embodiments of the present invention, an air knife includes an inlet through which air is supplied from an outside of the air knife, a chamber which stores the air flowing through the inlet, an outlet which is connected to the chamber and sprays the air stored in the chamber on a substrate, and a main body having a first lower end portion and a second lower end portion both inclined to a body reference line of the main body, wherein a plurality of protrusions are formed on the first lower end portion and projected toward the substrate.

The air knife may further include a throat which connects the chamber to the outlet. A cross-sectional shape of the plurality of protrusions is formed in at least one of a square, a triangle, a semicircle, and a parallelogram.

In still other exemplary embodiments of the present invention, a substrate drying apparatus includes a conveyor part which conveys a substrate, and an air knife, wherein the air knife includes an inlet through which air is supplied from an outside of the air knife, a chamber which stores the air flowing through the inlet, an outlet which is connected to the chamber and sprays the air stored in the chamber on the substrate, and a main body having a lower end portion extending from the outlet and past at least a portion of the chamber, wherein an angle between the lower end portion of the main body and a body reference line extended from the outlet is less than 40 degrees.

### BRIEF DESCRIPTION OF THE DRAWINGS

The above and other features and advantages of the present invention will become more apparent by describing exemplary embodiments thereof with reference to the accompanying drawings, in which:

FIG. 1 is a cross-sectional view illustrating an exemplary substrate drying apparatus according to an exemplary embodiment of the present invention;

FIG. 2 is a cross-sectional view illustrating an exemplary air knife according to a first exemplary embodiment of the present invention;

FIG. 3 is cross-sectional view for describing a vortex between an air knife and a substrate according to the prior art;

FIG. 4 is a cross-sectional view for describing the air current between the exemplary air knife and the exemplary substrate of FIG. 2;

FIG. 5 is a cross-sectional view illustrating an exemplary air knife according to a second exemplary embodiment of the present invention;

FIG. 6 is a cross-sectional view illustrating an exemplary air knife according to a third exemplary embodiment of the present invention;

FIG. 7 is an enlarged view showing area P of FIG. 6; and

FIG. 8 is a cross-sectional view illustrating an exemplary air knife according to a fourth exemplary embodiment of the present invention.

### DETAILED DESCRIPTION OF THE INVENTION

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

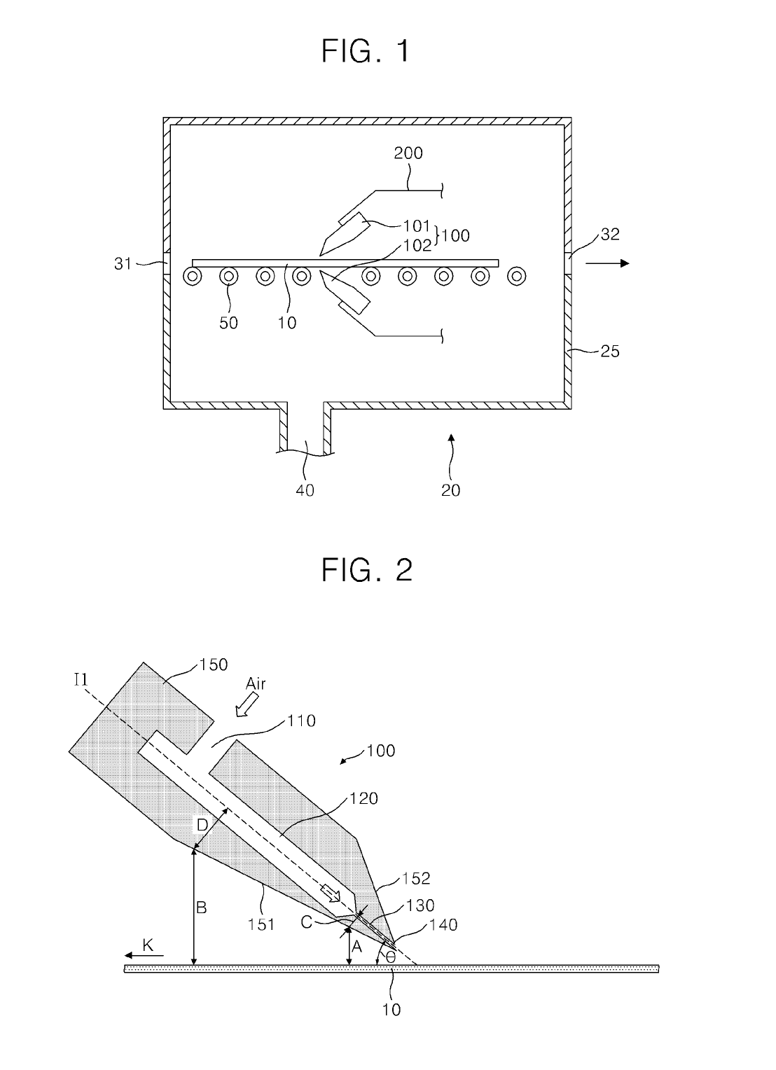

Hereinafter, exemplary embodiments of the present invention will now be described in detail with reference to FIGS. 1 to 8.

FIG. 1 is a cross-sectional view illustrating an exemplary substrate drying apparatus according to an exemplary embodiment of the present invention.

As shown in FIG. 1, a substrate drying apparatus includes a conveyor part 50 which conveys a substrate 10, an air knife 100 which sprays air on a surface of the substrate 10 to dry the substrate 10, and a drying module 20 which accommodates the conveyor part 50 and the air knife 100 therein. The drying module 20 includes a wall 25, at least substantially surrounding a portion of the conveyor part 50 upon which the substrate 10 is positioned relative to the air knife 100, to form a drying space. The wall 25 includes an entrance 31 through which the substrate 10 cleaned from the cleaning part (not shown) is entered, an exit 32 through which the substrate 10 dried within the drying module 20 exits, and a drain 40 through which cleaning agents and impurities are discharged.

The conveyor part 50 conveys the substrate 10, formed of glass or plastic material, in a prescribed direction, such as in a direction from the entrance 31 to the exit 32. The conveyor part 50 includes a plurality of rotating members, for example, rollers formed at the same height. The conveyor part 50 further includes a driver (not shown) to rotate the rollers in one direction.

The air knife 100 is arranged so as to be close to the surface of the substrate 10 when the substrate 10 passes by the air knife 100, and sprays air on the surface of the substrate 10 to dry the substrate 10. More specifically, the air knife 100 sprays the air supplied from an outside thereof on the surface of the substrate 10 to remove cleaning agents and impurities remaining on the substrate 10 and to dry the substrate 10. The cleaning agents may be de-ionized water and the like which do not damage the substrate 10.

In an exemplary embodiment, the air knife 100 includes an upper air knife 101 arranged above the substrate 10, and a lower air knife 102 arranged below the substrate 10. The upper air knife 101 and the lower air knife 102 are symmetrically arranged centering on the substrate 10 to dry the upper and lower surfaces of the substrate 10 conveyed by the conveyor part 50. Each of the upper and lower air knives 101 and 102 further includes an air supply pipe 200 connected to receive air from an external air supply unit (not shown).

Hereinafter, exemplary embodiments of the air knife according to the present invention will be described in more detail with reference to FIG. 2 to FIG. 8. For convenience of description, exemplary embodiments of the air knife will be described with respect to only one of an upper air knife and a lower air knife, and it should be understood that, in an exemplary embodiment including both an upper air knife 101 and a lower air knife 102, the air knives 101 and 102 may be similarly constructed.

FIG. 2 is a cross-sectional view illustrating an exemplary air knife according to a first exemplary embodiment of the present invention.

As shown in FIG. 2, the air knife 100 includes a main body 150, an inlet 110, a chamber 120, and an outlet 140. The air knife 100 further includes a throat 130 between the chamber 120 and the outlet 140.

Air supplied from the outside of the air knife 100 flows into the chamber 120 through the inlet 110. The inlet 110 is formed at a side of the main body 150 and has a prescribed width to effectively supply the air to the chamber 120. The air may be compressed air, and may be provided to the inlet 110 from the air supply pipe 200 shown in FIG. 1.

The chamber 120 is formed at the interior of the main body 150 to temporarily store the air supplied through the inlet 110. The chamber 120 is connected to the inlet 110 and to the throat 130. In an exemplary embodiment, the chamber 120 has a symmetrical structure based on a body reference line I1 extended from the throat 130. The body reference line I1 may also be referred to as a longitudinal axis of the throat 130, and in this exemplary embodiment, the longitudinal axis of the throat 130 is also the longitudinal axis of the chamber 120. However, the chamber 120 is not limited to the right and left symmetrical structure but may be formed in various forms in alternative exemplary embodiments thereof.

The throat 130 provides a path to spray the air stored in the chamber 120 to the outside of the main body 150. One side of the throat 130 is connected to the chamber 120, and the other side of the throat 130 is connected to the outlet 140. The throat 130 has a smaller width than the width of the chamber 120 so that the air stored in the chamber 120 is sprayed on the surface of the substrate 10 at high-pressure via the outlet 140.

The outlet 140 is formed at an end portion of the throat 130. The outlet 140 causes the air flowing through the throat 130 to be sprayed at a lower end portion of the main body 150 and onto the surface of the substrate 10. In an exemplary embodiment, the outlet 140 is opened with the same size as the cross-sectional area of the throat 130. The air knife 100 is arranged relative to the substrate 10 such that the outlet 140 is spaced apart from the surface of the substrate 10. For example, the outlet 140 may be spaced apart from the surface of the substrate 10 by about 3 mm to about 5 mm. The air sprayed from the outlet 140 removes the cleaning agents and impurities remaining on the surface of the substrate 10 after cleaning the substrate 10 so as to dry the substrate 10.

An upper end portion of the main body 150 is larger than the lower end portion of the main body 150. In other words, the upper end portion of the main body 150 and the lower end portion of the main body 150 are different in shape. For example, the upper end portion of the main body 150 may be formed to have a cross-sectional shape in the shape of a square or rectangle, and the lower end portion of the main body 150 may be formed to have a cross-sectional shape in the shape of a triangle.

A distance between the lower end portion of the main body 150 and the body reference line I1 increases as a distance increases from the outlet 140. To this end, the main body 150 includes a first lower end portion 151 and a second lower end portion 152, which both incline toward the body reference line I1 in a direction towards the outlet 140. A distance between the first lower end portion 151 and the substrate 10 increases as a distance of the first lower end portion 151 increases from the outlet 140. That is, a distance B between a point along the first lower end portion 151 spaced far away from the outlet 140 and the substrate 10 is longer than a distance A between a point along the first lower end portion 151 spaced closely to the outlet 140 and the substrate 10. Therefore, a cross-sectional area of the main body 150 decreases from a first cross-section taken perpendicularly with respect to the body reference line I1 and crossing both the chamber 120 and the first lower end portion 151, to a second cross-section taken perpendicularly with respect to the body reference line I1 and crossing both the throat 130 and the first lower end portion 151. In this exemplary embodiment, the first lower end portion 151 extends past at least a portion of the chamber 120.

Meanwhile, a distance D between a point along the first lower end portion 151 spaced far away from the outlet 140 and the body reference line I1 is longer than a distance C between a point along the first lower end portion 151 spaced closely to the outlet 140 and the body reference line I1.

In an exemplary drying operation, the air knife 100 is arranged so as to be inclined relative to the substrate 10 at a predetermined angle θ, for example, about 10° to about 50° with respect to the surface of the substrate 10 to effectively dry the substrate 10. If the air knife 100 is arranged to spray air at an angle of more than 50° with respect to the surface of the substrate 10, then a lot of air sprayed on the surface of the substrate 10 may flow into a space between the first lower end portion 151 and the substrate 10 along a moving direction K of the substrate 10. Accordingly, cleaning agents and impurities may flow into a dried area of the substrate 10. On the other hand, if the air knife 100 is arranged to spray air at an angle of less than 10° with respect to the surface of the substrate 10, then it is difficult to remove the cleaning agents and impurities attached to the surface of the substrate 10, thereby debasing drying abilities for the substrate 10.

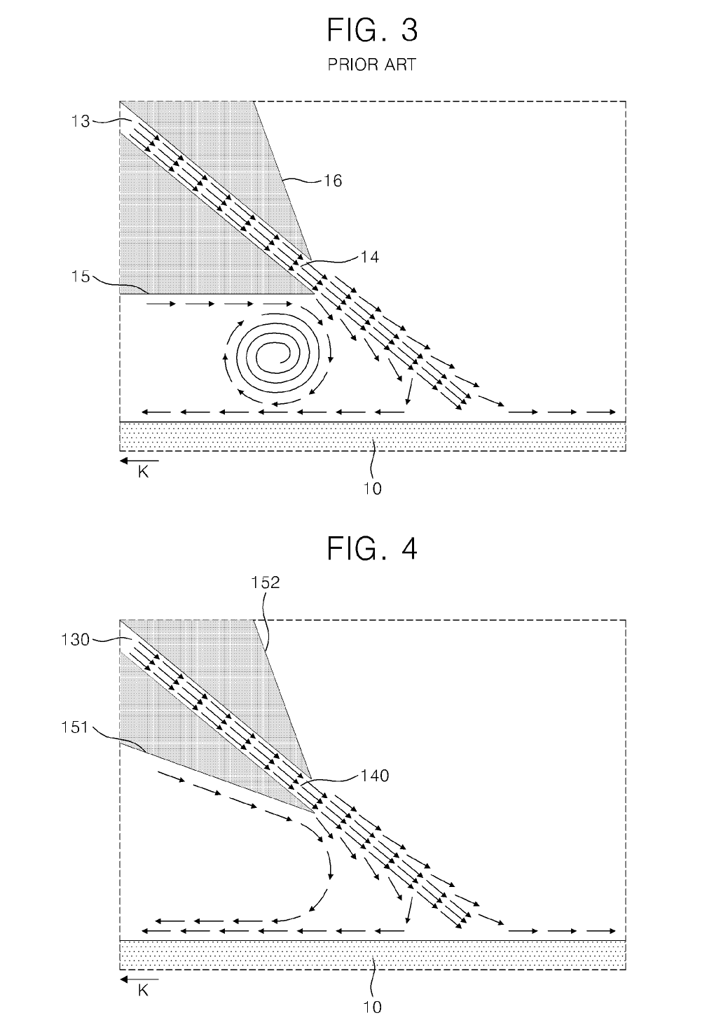

FIG. 3 is cross-sectional view for describing a vortex between an air knife and a substrate according to the prior art, and FIG. 4 is a cross-sectional view for describing air flow between the exemplary air knife and the substrate of FIG. 2.

As shown in FIG. 3, the conventional air knife, having the first and second lower end portions 15 and 16, sprays air having high pressure and air flux on the surface of the substrate 10 so as to dry the surface of the substrate 10. At this time, although a lot of the air passing through the throat 13 and sprayed from the outlet 14 is discharged in an opposite direction to the moving direction K of the substrate 10 while colliding with the surface of the substrate 10, a portion of the air sprayed from the outlet 14 flows in a same direction as the moving direction K of the substrate 10, that is, into the dried area of the substrate 10. In this case, a vortex is generated in a narrow space between the substrate 10 and the first lower end portion 15 by the air of high pressure.

To prevent the vortex, the air knife according to the exemplary embodiment of the present invention is formed, as shown in FIG. 4, such that a space between the first lower end portion 151 and the substrate 10 is gradually increased as a distance along the first lower end portion 151 increases from the outlet 140. Then, pressure of the air flowing into the space between the substrate 10 and the first lower end portion 151 is dispersed, and the vortex air current is prevented.

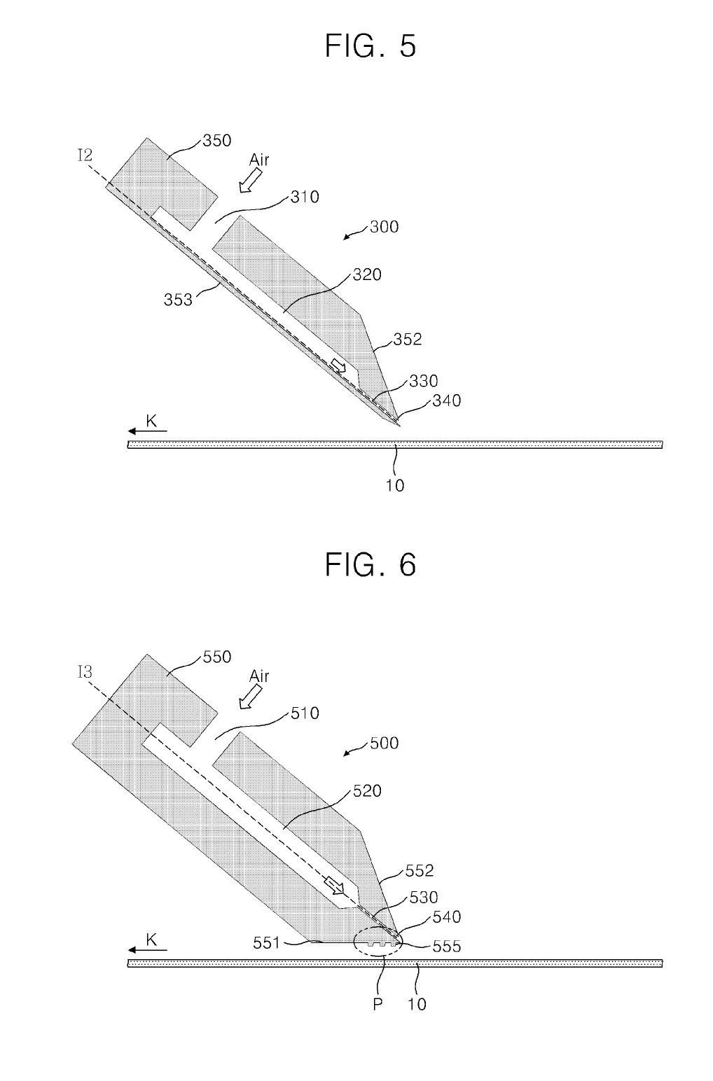

FIG. 5 is a cross-sectional view illustrating an exemplary air knife according to a second exemplary embodiment of the present invention.

As shown in FIG. 5, a main body 350 of an air knife 300 has a dissymmetrical structure based on a body reference line I2 extended from a throat 330. The body reference line I2 may also be considered a longitudinal axis of the throat 330. In this exemplary embodiment, the longitudinal axis of the throat 330 is not the same as the longitudinal axis of the chamber 320. One side of a chamber 320 is directly extended from the throat 330. Adjacent the throat 330, the chamber 320 has a trapezoid structure in which a cross-sectional area of a lower end portion of the chamber 320 is gradually decreased towards the throat 330 so as to be connected to the throat 330 with a narrow cross-sectional area.

For at least a substantial portion of a first side 353 of the main body 350, the first side 353 makes an identical distance, or a substantially identical distance, from the body reference line I2. In other words, a distance between the first side 353 and the body reference line I2 is substantially the same for nearly the entire first side 353. The air knife 300 is arranged relative to the substrate 10 such that the distance between the first side 353 of the main body 350 and the substrate 10 gradually increases as a distance along the first side 353 of the main body 350 increases from an outlet 340. A second side of the main body 350 has an inlet 310 which accesses the chamber 320. A cross-sectional area of a lower end portion 352 of the second side of the main body 350 gradually decreases towards the outlet 340 so as to be connected to the outlet 340. The second side of the main body 350 may be formed in a similar shape to the chamber 320. The first side 353 of the main body 350 is formed with a proper thickness to prevent damage of the main body 350 due to the pressure of the air.

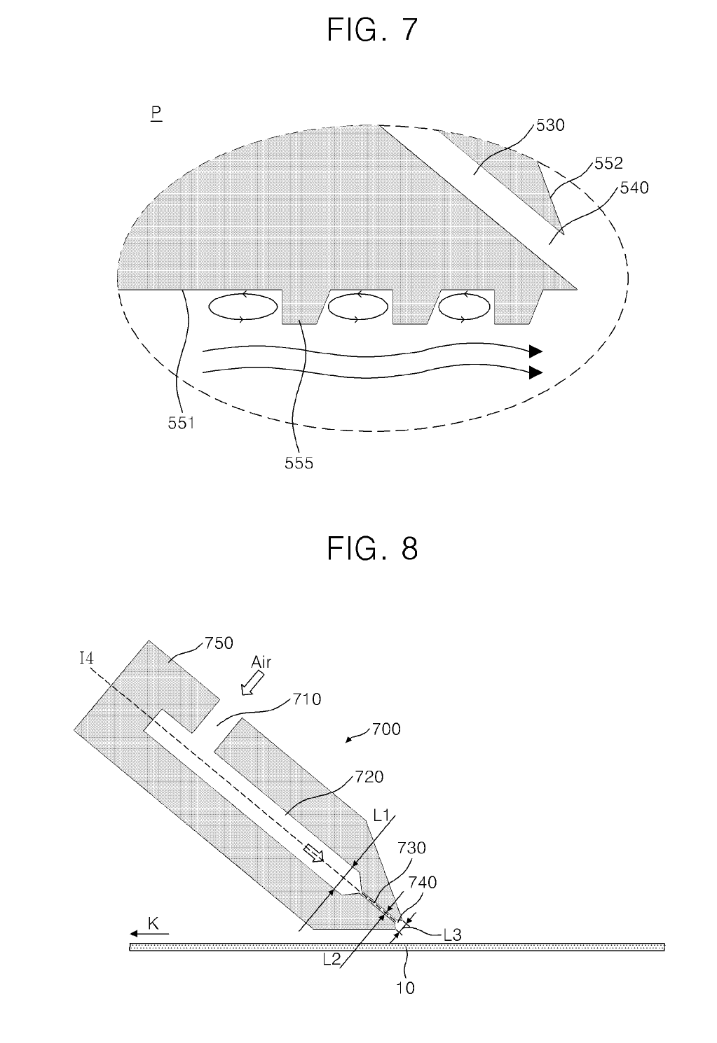

FIG. 6 is a cross-sectional view illustrating an exemplary air knife according to a third exemplary embodiment of the present invention, and FIG. 7 is an enlarged view showing area P of FIG. 6.

As shown in FIG. 6 and FIG. 7, an air knife 500 includes a main body 550, an inlet 510 through which air is supplied from an outside of the air knife 500, a chamber 520 which stores air flowing into the inlet 510, and an outlet 540 which sprays the air stored in the chamber 520 on a surface of a substrate 10 while being connected to the chamber 520 to dry the substrate 10. The air knife 500 further includes a throat 530 between the chamber 520 and the outlet 540. A first lower end portion 551 and a second lower end portion 552 of the main body 550 are inclined to a body reference line I3 in a direction towards the outlet 540. The first lower end portion 551 has a plurality of protrusions 555 projected toward the substrate 10 to form stepped portions.

To avoid repeated descriptions, a detailed description of the same elements within the air knife 500 as those shown in FIG. 1 to FIG. 4 will be omitted.

The plurality of protrusions 555 projected toward the substrate 10 is formed at the first lower end portion 551 to prevent vortex air current. For example, the protrusions 555 with a height of about 1 mm are projected from the first lower end portion 551 and toward the substrate 10. A cross-section of the protrusions 555 is formed in the shape of at least one of a square, a triangle, a semicircle, and a parallelogram. The protrusions 555 are at least provided within an area of the first lower end portion 551 adjacent the outlet 540.

The protrusions 555 disperse pressure of air by purposely forming small-sized vortex air currents between the protrusions 555 so that large-sized vortex air current between the first lower end portion 551 and the substrate 10 may be prevented. As a result, cleaning agents and impurities do not flow into a dried area of the substrate 10. The above-mentioned method is similar to a method to prevent vortex air current in a heavy vehicle by forming convexo-concave protrusions at the front of a trailer when velocity of a vehicle, a truck for example, is decreased due to vortex air current generated between a trailer truck and a trailer.

FIG. 8 is a cross-sectional view illustrating an exemplary air knife according to a fourth exemplary embodiment of the present invention.

As shown in FIG. 8, an air knife 700 includes a main body 750, an inlet 710 through which air is supplied from an outside of the air knife 700, a chamber 720 which stores the air flowing into the inlet 710, an outlet 740 which sprays the air stored in the chamber 720 on a surface of the substrate 10 while being connected to the chamber 720 to dry the substrate 10, and a throat 730 which connects the chamber 720 to the outlet 740.

To avoid repeated descriptions, a detailed description of the same elements within air knife 700 as those in FIG. 1 to FIG. 4 will be omitted.

A cross-sectional area of a part connecting the chamber 720 to the throat 730 is gradually decreased as the chamber 720 is directed toward the outlet 740. In other words, a cross-sectional area L1 of the chamber 720 is larger than a cross-sectional area L2 of the throat 730, and the cross-sectional area of the chamber 720 decreases from L1 to L2 to connect with the throat 730.

Meanwhile, a cross-sectional area of a part connecting the throat 730 to the outlet 740 gradually increases towards the outlet 740. In other words, a cross-sectional area L3 of the outlet 740 is larger than the cross-sectional area L2 of the throat 730.

Since air flows from the throat 730 of a relatively narrow space to the outlet 740 of a relatively wide space and high air pressure is changed to low air pressure, the velocity of the air is increased. Accordingly, when the air supplied in the chamber 720 through the inlet 710 passes through the throat 730 and the air passed through the throat 730 is sprayed on the surface of the substrate 10 through the outlet 740, the velocity of the air is remarkably increased. As a result, the performance of the air knife 700 capable of drying the substrate 10 is improved.

While particular exemplary embodiments have been described, combinations of features of these exemplary embodiments would also be within the scope of these embodiments.

Furthermore, a method of drying a substrate using the exemplary embodiments of an air knife is made possible. An exemplary method may include arranging an air knife relative to a surface of a substrate, moving the substrate in a first direction, directing air from an outlet of the air knife onto the substrate, and preventing vortex air currents from generating between a lower end portion of the air knife and the surface of the substrate. Preventing vortex air currents may include at least one of increasing a distance from the substrate to the lower end portion as a distance of a point along the lower end portion increases from the outlet, and providing protrusions on the lower end portion adjacent the outlet to form vortex air currents between the protrusions. The method may further include increasing a spraying velocity of air through the outlet by increasing a cross-sectional area of the outlet to be greater than a cross-sectional area of a throat of the air knife, wherein the throat has a smaller cross-sectional area than a cross-sectional area of a chamber of the air knife.

The air knife according to exemplary embodiments of the present invention prevents a vortex generated at a rear side of a spray position by changing a structure of the lower end portion of the main body. Accordingly, the cleaning agents and the impurities do not flow into a dried area of the substrate during substrate drying processes, thereby preventing a quality defect in a subsequent process. Furthermore, in the air knife according to exemplary embodiments of the present invention, a structure of the outlet is changed so that the spraying velocity of the air spraying through the outlet is increased, and thus drying ability for the substrate is improved.

Although exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. An air knife comprising:
an inlet through which air is supplied from an outside of the air knife;
a chamber which stores the air flowing through the inlet;
an outlet which is connected to the chamber and sprays the air stored in the chamber on a substrate; and
a main body having a lower end portion extending from the outlet and past at least a portion of the chamber, wherein an angle between the lower end portion of the main body and a body reference line extended from the outlet is less than 40 degrees.

2. The air knife of claim 1, further comprising a throat that connects the chamber to the outlet.

3. The air knife of claim 2, wherein the air sprayed through the outlet makes a predetermined angle with respect to a surface of the substrate.

4. The air knife of claim 3, wherein the predetermined angle is about 10° to about 50°, wherein the predetermined angle is greater than the angle between the lower end portion of the main body and a body reference line.

5. The air knife of claim 2, wherein a distance between the lower end portion of the main body and the substrate increases as a distance increases from the outlet.

6. The air knife of claim 2, wherein the body reference line is a longitudinal axis passing longitudinally through the chamber and the throat, the chamber having a larger cross-sectional area than the throat, and the distance between the lower end portion of the main body and the body reference line gradually increases from the outlet to a first point of the chamber connected to the throat and from the first point of the chamber to a second point of the chamber closer to the inlet.

7. The air knife of claim 1, wherein the angle is more preferably about 0° to about 30°

8. The air knife of claim 7, wherein a distance between the one side of the main body and the substrate increases as a distance increases from the outlet.

9. The air knife of claim 1 further comprising;
a throat which connects the chamber to the outlet,
wherein a cross-sectional area of a first part connecting the chamber and the throat gradually decreases toward the throat, and a cross-sectional area of a second part connecting the throat and the outlet gradually increases toward the outlet.

10. An air knife comprising:
an inlet through which air is supplied from an outside of the air knife;
a chamber which stores the air flowing through the inlet;
an outlet which is connected to the chamber and sprays the air stored in the chamber on a substrate; and
a main body having a first lower end portion and a second lower end portion both inclined to a body reference line of the main body,
wherein a plurality of protrusions is formed on the first lower end portion and projected toward the substrate.

11. The air knife of claim 10, further comprising a throat which connects the chamber to the outlet.

12. The air knife of claim 9, wherein a cross-sectional shape of the plurality of protrusions is formed in at least one of a square, a triangle, a semicircle, and a parallelogram.

13. A substrate drying apparatus comprising:
a conveyor part which conveys a substrate; and
an air knife,
wherein the air knife includes an inlet through which air is supplied from an outside of the air knife; a chamber which stores the air flowing through the inlet; an outlet which is connected to the chamber and sprays the air stored in the chamber on the substrate; and a main body having a lower end portion extending from the outlet and past at least a portion of the chamber, wherein an angle between the lower end portion of the main body and a body reference line extended from the outlet is less than 40 degrees.

14. The substrate drying apparatus of claim 13, further comprising a drying module that accommodates the conveyor part and the air knife therein.

15. The substrate drying apparatus of claim 14, wherein the conveyor part includes a plurality of rotating members formed at a same height as each other.

16. The substrate drying apparatus of claim 15, wherein the plurality of rotating members includes rollers.

17. The substrate drying apparatus of claim 13, wherein the air sprayed through the outlet makes a predetermined angle with respect to a surface of the substrate.

18. The substrate drying apparatus of claim 17, wherein the predetermined angle is about 10° to about 50°, wherein the predetermined angle is greater than the angle between the lower end portion of the main body and a body reference line.

19. The substrate drying apparatus of claim 13, wherein the lower end portion forms a nonzero angle with respect to a surface of the substrate to prevent a vortex of air from occurring between the first lower end portion and the substrate.

20. The substrate drying apparatus of claim 13, wherein a distance between the substrate and the lower end portion increases as a distance increases from the outlet to prevent a vortex of air from occurring between the first lower end portion and the substrate.
